(19) United States
(12) Patent Application Publication
(10) Pub. No.: US 2022/0105587 A1
(43) Pub. Date: Apr. 7, 2022

(54) COOLING DEVICE

(71) Applicant: KAWASAKI JUKOGYO KABUSHIKI KAISHA, Kobe-shi, Hyogo (JP)

(72) Inventors: Yasuaki KIDA, Kobe-shi (JP); Hitoshi NARIAI, Nishinomiya-shi (JP); Kazumi FUKUHARA, Akashi-shi (JP)

(73) Assignee: KAWASAKI JUKOGYO KABUSHIKI KAISHA, Kobe-shi, Hyogo (JP)

(21) Appl. No.: 17/312,294

(22) PCT Filed: Dec. 6, 2019
(86) PCT No.: PCT/JP2019/047878

§ 371 Date: Jun. 9, 2021

(30) Foreign Application Priority Data
Dec. 13, 2018 (JP) 2018-233297

(51) Int. Cl. B23K 11/30; B23K 11/31; B23K 11/36; B25J 19/00

(52) U.S. Cl. CPC B23K 11/3054; B25J 19/0054; B23K 11/36; B23K 11/315

(57) ABSTRACT

A cooling device includes a refrigerant circulation channel, and a pump configured to pump refrigerant in the refrigerant circulation channel A heat generating part of an articulated robot includes a heat generating part of an end effector, and a part of the refrigerant circulation channel is formed as a first heat exchanging part configured to exchange heat between the heat generating part of the end effector and the refrigerant, and another part of the refrigerant circulation channel is formed as a radiator. The radiator is a passive radiator, and is attached in an exposed state to a part of the surface of an arm, configured to move in a space when a joint of the arm is driven.

### TECHNICAL FIELD

The present disclosure relates to a cooling device which cools a heat generating part of an articulated robot.

### BACKGROUND ART

Conventionally, a spot welding robot which automatically performs spot welding is known. Generally, the spot welding robot is an articulated robot in which a spot welding gun is attached to a tip-end part of an articulated arm Electrode tips of the spot welding gun become high temperature instantly. When the electrode tips melt, the weld performance of the electrode tips falls, and as a result, the weld efficiency falls. Therefore, the spot welding robot has a cooling device for cooling the spot welding gun including the electrode tips.

For example, a spot welding robot disclosed in Patent Document 1 is provided in a robot body (i.e., an articulated arm) with a cooling device for cooling a spot welding gun. This cooling device includes a water storage tank, a water supply hose which supplies water inside the tank to the spot welding gun, a drain hose which returns the cooling water which cooled the spot welding gun to the tank, a pump which sends the cooling water inside the tank to the water supply hose, and a fan which cools the cooling water flowing through the drain hose.

A spot welding robot disclosed in Patent Document 2 is provided in a weld gun body with a cooling device which cools a spot welding gun and a welding transformer mounted on the spot welding gun. This cooling device has a circulating pump and a circulation channel through which refrigerant pumped by the circulating pump flows. The circulation channel is a channel where the refrigerant circulates through the circulating pump, the welding transformer, the weld gun body, and a radiator. The refrigerant which flows through the radiator is cooled by a radiator fan as illustrated in Patent Document 2.

In the cooling devices of Patent Documents 1 and 2, the refrigerant circulates through the spot welding gun, or the spot welding gun and the arm. These cooling devices are unnecessary to be provided with a long cooling piping from a source of the refrigerant (for example, a cock of water supply), which is installed away from the spot welding robot, to the spot welding robot.

### REFERENCE DOCUMENTS OF CONVENTIONAL ART

### Patent Documents

[Patent Document 1] JP1998-263843A
[Patent Document 2] JP2004-122203A

### DESCRIPTION OF THE DISCLOSURE

During operation of the spot welding robot, the arm operates so that the spot welding gun sequentially moves to a plurality of welding locations. Since the arm operates at high speed, it is desirable for each component attached to the arm to suppress a projection from the surface of the arm. Moreover, in order to reduce load which acts on the arm, the components attached to the arm are desirably smaller in the number.

### Problem to be Solved by the Disclosure

The present disclosure is made in view of the above situation, and one purpose thereof is to provide a cooling device configured to cool a heat generating part of an articulated robot, where the number of components is reduced, and a projection of components attached to an arm from the surface of the arm is suppressed.

### SUMMARY OF THE DISCLOSURE

A cooling device according to one aspect of the present disclosure is a cooling device configured to cool a heat generating part of an articulated robot provided with an arm having a plurality of joints, and an end effector attached to a tip-end part of the arm. The cooling device includes a refrigerant circulation channel, and a pump configured to pump refrigerant in the refrigerant circulation channel. The heat generating part includes the heat generating part of the end effector. A part of the refrigerant circulation channel is formed as a first heat exchanging part configured to exchange heat between the heat generating part of the end effector and the refrigerant, and another part of the refrigerant circulation channel is formed as a radiator. The radiator is a passive radiator, and is attached in an exposed state to a part of the surface of the arm, configured to move in a space when the joint of the arm is driven. Here, the “passive radiator” means a radiator which cools the refrigerant by natural heat radiation without using a radiator fan for radiating heat of the refrigerant. The passive radiator may also be referred to as a “fanless radiator.”

According to the cooling device described above, when the radiator moves in the space in association with the operation of the arm of the articulated robot, the flow of air occurs around the radiator and it urges the heat exchange between the refrigerant which flows through the radiator and the air. That is, as compared with a case where the refrigerant is cooled in the natural heat radiation, it can cool the refrigerant effectively. Therefore, a radiator fan which normally accompanying the radiator can be omitted. By the omission of the radiator fan, the number of components of the cooling device can be reduced, a projection of components attached to the arm of the robot is suppressed, and energy can be reduced. Further, since the passive radiator does not require electric power, wiring of an electric system becomes unnecessary, thereby increasing a degree of freedom in the layout of the radiator.

### Effect of the Disclosure

According to the present disclosure, a cooling device configured to cool a heat generating part of an articulated robot can be provided, where the number of components is reduced, and a projection of components attached to an arm from the surface of the arm is suppressed.

### BRIEF DESCRIPTION OF DRAWINGS

FIG. 1 is an outline configuration diagram of an articulated robot having a cooling device according to one embodiment of the present disclosure.

FIG. 2 is a view illustrating a configuration of a control system of the articulated robot.

FIG. 3 is a view illustrating a configuration of the cooling device according to one embodiment of the present disclosure.

FIG. 4 is a view illustrating the articulated robot when an arm is at a standby position.

FIG. 5 is a view illustrating a configuration of a cooling device according to Modification 1.

FIG. 6 is a view illustrating a configuration of a cooling device according to Modification 2.

FIG. 7 is an outline configuration diagram of an articulated robot having the cooling device according to Modification 2.

### MODES FOR CARRYING OUT THE DISCLOSURE

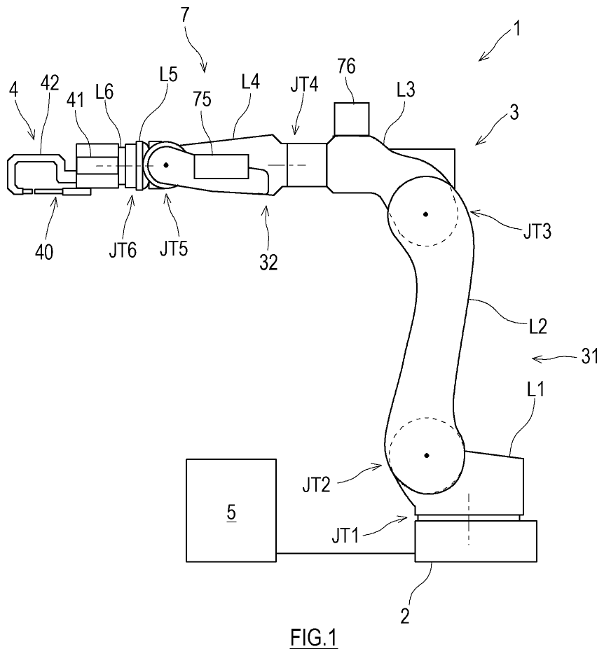

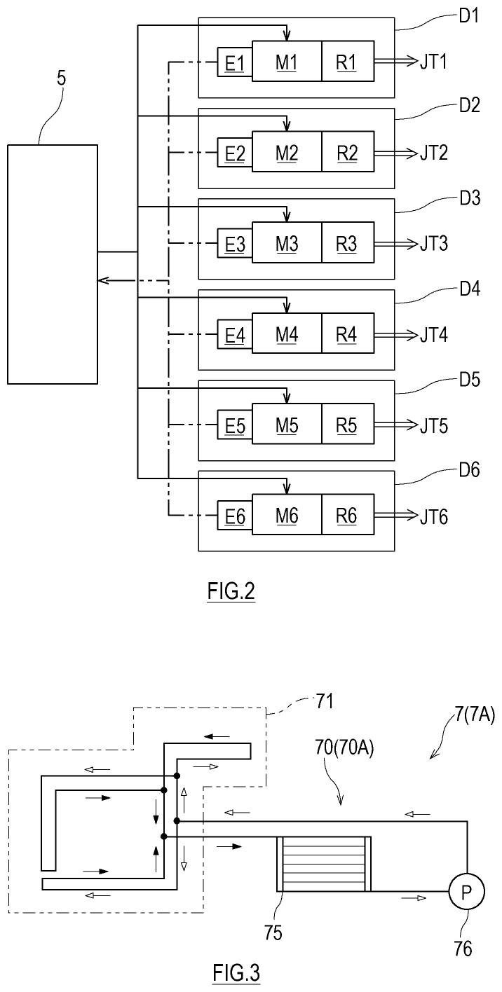

Next, embodiments of the present disclosure will be described with reference to the drawings. FIG. 1 is an outline configuration diagram of an articulated robot 1 having a cooling device 7 according to one embodiment of the present disclosure, and FIG. 2 is a view illustrating a configuration of a control system of the articulated robot. Note that, below, although a six-axis vertical articulated robot is described as one example of the articulated robot 1 (hereinafter, referred to as “the robot 1”), the cooling device 7 according to the present disclosure may be widely applied to articulated robots of vertical articulated type and horizontal articulated type, and with any number of axes.

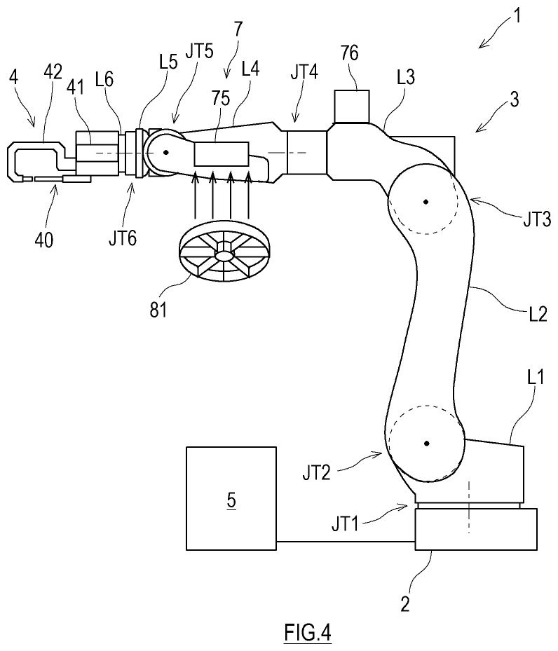

The robot 1 illustrated in FIG. 1 includes a base 2, a robotic arm (hereinafter, referred to as “the arm 3”) supported by the base 2, an end effector 4 which is attached to a hand part of the arm 3, and a controller 5 which governs operation of the robot 1. The robot 1 is also provided with the cooling device 7 (see FIG. 4) which cools a heat generating part of the arm 3 and the end effector 4.

[Arm 3]

The arm 3 includes six links L1-L6 which are serially coupled to each other through joints JT1-JT6. A base-end part of the first link L1 is supported by the base 2 through the first joint JT1. The first joint JT1 causes the first link L1 to swivel with respect to the base 2. A tip-end part of the first link L1 and a base-end part of the second link L2 are coupled to each other through the second joint JT2. The second joint JT2 rotates the second link L2 in a vertical plane with respect to the first link L1. That is, the second joint JT2 is a pivot joint. A tip-end part of the second link L2 and a base-end part of the third link L3 are coupled to each other through the third joint JT3. The third joint JT3 rotates the third link L3 in the vertical plane with respect to the second link L2. That is, the third joint JT3 is a pivot joint.

A tip-end part of the third link L3 and a base-end part of the fourth link L4 are coupled to each other through the fourth joint JT4. The fourth joint JT4 twistingly rotates the fourth link L4 with respect to the third link L3. A tip-end part of the fourth link L4 and a base-end part of the fifth link L5 are coupled to each other through the fifth joint JT5. The fifth joint JT5 bendingly rotates the fifth link L5 with respect to the fourth link L4. A tip-end part of the fifth link L5 and a base-end part of the sixth link L6 are coupled to each other through the sixth joint JT6. The sixth joint JT6 twistingly rotates the sixth link L6 with respect to the fifth link L5.

The second link L2 may be referred to as a “lower arm 31” of the arm 3. Moreover, the third links L3 and L4 may be referred to as an “upper arm 32” of the arm 3. The upper arm 32 is coupled to a tip-end part of the lower arm 31 through the third joint JT3 which is the pivot joint.

As illustrated in FIG. 2, the joints JT1-JT6 are provided with joint actuators D1-D6, respectively. The joint actuators D1-D6 have substantially the same or corresponding structure. That is, each of the joint actuators D1-D6 includes a rotary joint (not illustrated) which pivotably couples the links, a servomotor M which is a drive source, and a gear-type reduction gear R coupled to an output shaft of the servomotor M. Note that, in FIG. 2, numbers attached to the reference characters M, R, E, and D are associated with numbers of the first to sixth joints JT1-JT6. The reduction gear R amplifies rotating torque of the servomotor M and transmits it to the corresponding rotary joint. The servomotor M is provided with a rotary encoder E which detects a rotation displacement of the output shaft.

[End Effector 4]

Returning to FIG. 1, the end effector 4 is attached to the tip-end part of the sixth link L6 of the arm 3. A spot welding gun 40 as one example of the end effector 4 includes a weld gun body 42 which includes weld electrodes which apply pressure to a weldment and apply electric current, and a welding transformer 41 which converts electric current from a welding power source (not illustrated) into large current and supplies it to the weld electrodes. The spot welding gun 40 includes at least one heat generating part provided with the weld electrodes and the welding transformer 41 of the weld gun body 42.

[Controller 5]

The controller 5 may be embodied as a kind of computer, such as a PLC (programmable controller). The controller 5 includes an arithmetic unit (processor) comprised of a CPU, an MPU, or a GPU, and a volatile and nonvolatile storage device (memory). The arithmetic unit performs processing for controlling operation of the robot 1 by reading and executing various programs stored in the storage device.

The controller 5 calculates a target pose (a position and a posture) after a given control period based on a rotation position of the servomotor M detected by the rotary encoder E and a teaching point data stored in the storage device in advance. Then, the controller 5 supplies driving power to the servomotor M so that the arm 3 becomes the target pose after the given control period.

[Cooling Device 7]

FIG. 3 is a view illustrating a configuration of the cooling device 7. The cooling device 7 (7A) illustrated in FIG. 3 includes a refrigerant circulation channel 70 and a pump 76 which pumps refrigerant in the refrigerant circulation channel 70. In this embodiment, although the pump 76 is attached to the arm 3, the pump 76 may be attached to the base 2 or the end effector 4.

A part of the refrigerant circulation channel 70 is formed as a first heat exchanging part 71 which performs a heat exchange between the heat generating part of the spot welding gun 40 which is the end effectors 4 and the refrigerant. The first heat exchanging part 71 includes a channel circulating the weld gun body 42 of the spot welding gun 40, and a channel circulating the welding transformer 41.

Another part of the refrigerant circulation channel 70 is formed as a radiator 75. The radiator 75 is provided to the refrigerant circulation channel 70, between an outlet of the first heat exchanging part 71 and an inlet of the pump 76. In the refrigerant circulation channel 70, a tank (not illustrated) which temporarily stores the refrigerant may be provided between an outlet of the radiator 75 and an inlet of the pump 76. The tank may be provided inside of the arm 3, for example.

The radiator 75 has an inlet tank, an outlet tank, and a radiator core which connects the inlet tank to the outlet tank, similar to common radiators. The radiator core is comprised of multiple-row tubes through which the refrigerant passes, and fins provided to the surface of the tubes. Although the radiator 75 according to this embodiment is a side-flow type, the radiator 75 may be a down-flow type.

The radiator 75 is a so-called “passive radiator.” Here, the “passive radiator” means a radiator which cools the refrigerant by natural heat radiation without using a radiator fan for radiating heat of the refrigerant. The passive radiator may also be referred to as a “fanless radiator.”

The radiator 75 is attached to a part of the surface of the arm 3 which moves in the space when the joints JT1-JT6 of the arm 3 are driven in a state where at least the radiator core is exposed. In this embodiment, the entire radiator 75 is attached to the upper arm 32 of the arm 3 in the exposed state, without being covered with a cover. The mounting position of the radiator 75 is desirably at the upper arm 32 of the arm 3, more preferably, at the tip-end part of the upper arm 32 with a large moving amount when operating the arm 3.

In the cooling device 7 having the above configuration, the refrigerant circulates through the refrigerant circulation channel 70 by operation of the pump 76. The refrigerant may be fluid which is generally used as refrigerant, such as water. The refrigerant exchanges heat with the heat generating part of the end effector 4 while passing through the first heat exchanging part 71 to cool the heat generating part of the end effector 4. The refrigerant heated by the first heat exchanging part 71 exchanges heat with air while passing through the radiator 75 and radiates the heat. The refrigerant cooled by the radiator 75 is again pumped to the first heat exchanging part 71 while passing through the pump 76.

In the cooling device 7, the radiator 75 moves in the space in association with the operation of the arm 3 of the robot 1. Therefore, a flow of air occurs around the radiator 75 and the air flow urges the heat exchange between the refrigerant which flow through the radiator 75 and the air.

FIG. 4 is a view illustrating the robot 1 when the arm 3 is at a standby position. As illustrated in FIG. 4, before and after a work, and while waiting for the next workpiece which is conveyed during a work, the arm 3 of the robot 1 is located at the given standby position and maintains a given standby posture. The standby position and the standby posture are taught to the robot 1 in advance.

The cooling device 7 is further provided with an air blower 81. The air blower 81 is not attached to the arm 3 or the end effector 4 of the robot 1, but it is physically independent from the robot 1. The air blower 81 may be placed on a floor where the robot 1 is installed so as to be adjacent to the robot 1, or may be suspended from a ceiling in a space where the robot 1 is installed. Note that, although the air blower 81 is independent from the robot 1, the drive (ON/OFF) of the air blower 81 may be interlocked with the operation of the robot 1.

The air blower 81 is disposed so that the radiator 75 attached to the arm 3 is located at an air sending location of the air blower 81 when the arm 3 of the robot 1 is at the standby position. The blowing direction of the air blower 81 may be horizontal, or may be downward or upward. The air blower 81 is desirably disposed so as not to affect the operation of the robot 1. Moreover, the air blower 81 may be always operated, or may be operated only when the arm 3 is at the standby position.

[Modification 1 of Cooling Device 7]

Modification 1 of the cooling device 7 (7A) according to the above embodiment is described. FIG. 5 is a view illustrating a configuration of the cooling device 7 (7B) according to Modification 1. The cooling device 7 (7B) is comprised of the refrigerant circulation channel 70 (70A) of the cooling device 7 (7A) according to the above embodiment which is further provided with a second heat exchanging part 72.

The heat generating part of the robot 1 includes the joint actuators D1-D6 which are heat generating parts of the arm 3. In more detail, the servomotors M and the reduction gears R included in the joint actuators D1-D6 correspond to the heat generating parts of the arm 3. A part of the refrigerant circulation channel 70 other than the first heat exchanging part 71, the radiator 75, and the pump 76, is formed as the second heat exchanging part 72 which exchanges heat between the joint actuators D1-D6 and the refrigerant.

The second heat exchanging part 72 is provided to the refrigerant circulation channel 70 (70B), downstream of the pump 76 and upstream of the first heat exchanging part 71. Note that the “upstream” of the refrigerant circulation channel 70 means upstream in the flow of the refrigerant, and the “downstream” of the refrigerant circulation channel 70 means downstream in the flow of the refrigerant.

For example, the second heat exchanging part 72 may be at least one of a refrigerant passage circulating inside the servomotor M, a refrigerant jacket formed around the servomotor M, a refrigerant passage circulating inside the reduction gear R, and a refrigerant jacket formed around the reduction gear R.

The second heat exchanging part 72 may be provided to at least one of the joint actuators D1-D6. Moreover, the second heat exchanging part 72 may be provided to at least one of the joint actuator D2 of the second joint JT2 and the joint actuator D3 of the third joint JT3, which are particularly large in the heat generating amount among the joint actuators D1-D6. Although the refrigerant circulation channel 70 illustrated in FIG. 5 includes one second heat exchanging part 72, a plurality of second heat exchanging parts 72 located in series or in parallel are formed in the refrigerant circulation channel 70 when the cooling device 7 cools the plurality of joint actuators D1-D6.

In the cooling device 7 (7B) having the above configuration, the refrigerant pumped by the pump 76 first cools the joint actuators D1-D6 while passing through the second heat exchanging part 72, and then cools the end effector 4 (spot welding gun 40) while passing through the first heat exchanging part 71, then radiates heat while passing through the radiator 75, and returns to the pump 76.

[Modification 2 of Cooling Device 7]

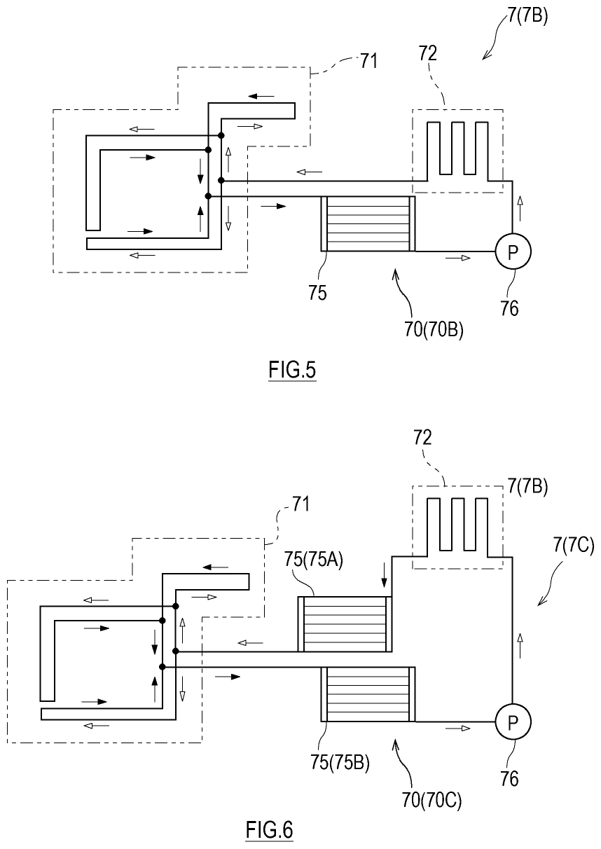

Modification 2 of the cooling device 7 (7A) according to the above embodiment is described. FIG. 6 is a view illustrating a configuration of the cooling device 7 (7C) according to Modification 2. The cooling device 7 (7C) is comprised of the refrigerant circulation channel 70 (70B) of the cooling device 7 (7B) according to the above Modification 1 in which a part between the second heat exchanging part 72 and the first heat exchanging part 71 is formed as a radiator 75 (75A). That is, the refrigerant circulation channel 70 (70C) has a first radiator 75 (75A) downstream of the second heat exchanging part 72 and upstream of the first heat exchanging part 71, and has a second radiator 75 (75B) downstream of the first heat exchanging part 71 and upstream of the pump 76.

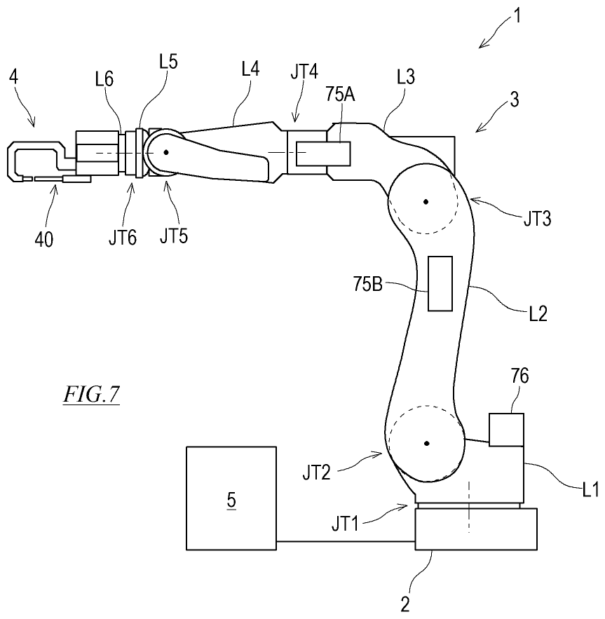

FIG. 7 is an outline configuration diagram of the robot 1 having the cooling device 7 (7C) according to Modification 2. In the robot 1 illustrated in FIG. 7, the first radiator 75A of the cooling device 7 (7C) is attached to the third link L3 of the arm 3 of the robot 1, and the second radiator 75B is attached to the second link L2. Thus, a plurality of radiators 75 may be disposed dividedly in the plurality of links.

In the cooling device 7 (7C) having the above configuration, the refrigerant pumped by the pump 76 first cools the joint actuators D1-D6 while passing through the second heat exchanging part 72, then radiates heat while passing through the first radiator 75A, then cools the end effector 4 (spot welding gun 40) while passing through the first heat exchanging part 71, finally radiates heat while passing through the second radiator 75B, and returns to the pump 76. Thus, in the cooling device 7 (7C), since the refrigerant before flowing into the first heat exchanging part 71 after flowing out of the second heat exchanging part 72 radiates the heat by the first radiator 75A, it can cool the end effector 4 more effectively.

As described above, the cooling device 7 according to this embodiment (and Modifications 1 and 2 thereof) is the cooling device 7 which cools the heat generating part of the robot 1 provided with the arm 3 having the plurality of joints JT1-JT6 and the end effector 4 which is attached to the tip-end part of the arm 3, and includes the refrigerant circulation channel 70 and the pump 76 which pumps the refrigerant in the refrigerant circulation channel 70. The heat generating part of the robot 1 includes the heat generating part of the end effector 4 and a part of the refrigerant circulation channel 70 is formed as the first heat exchanging part 71 which exchanges heat between the heat generating part of the end effector 4 and the refrigerant, and another part of the refrigerant circulation channel 70 is formed as the radiator 75. This radiator 75 is the passive radiator, and is attached to a part of the surface of the arm 3 which moves in the space in the exposed state when the joints JT1-JT6 of the arm 3 are driven.

According to the above cooling device 7, when the radiator 75 moves in the space in association with the operation of the arm 3 of the robot 1, the flow of air occurs around the radiator 75 and it urges the heat exchange between the refrigerant which flows through the radiator 75 and the air. That is, as compared with a case where the refrigerant is cooled by the radiator 75 in the natural heat radiation, it can cool the refrigerant effectively. Therefore, a radiator fan which normally accompanying the radiator 75 can be omitted. By the omission of the radiator fan, the number of components of the cooling device 7 can be reduced, a projection of components attached to the arm 3 of the robot 1 is suppressed, and energy can be reduced. Further, since the passive radiator does not require electric power, wiring of an electric system becomes unnecessary, thereby increasing a degree of freedom in the layout of the radiator 75.

As described in the above embodiment (and Modifications 1 and 2 thereof), the radiator 75 of the cooling device 7 may be attached to the upper arm 32 of the arm 3 of the robot 1. Here, the radiator 75 is desirably attached to the tip-end part of the upper arm 32. Note that the arm 3 has the lower arm 31 and the upper arm 32 coupled to the tip-end part of the lower arm 31.

Generally, during the operating period of the robot 1, a point on the surface of the upper arm 32 moves faster than a point on the surface of the lower arm 31. Further, a point on the surface of the tip-end part of the upper arm 32 moves faster than a point on the surface of the base-end part of the upper arm 32. Therefore, the flow of air which is formed around the radiator 75 by the operation of the arm 3 is generally faster when the radiator 75 is attached to the upper arm 32 than when the radiator 75 is attached to the lower arm 31. Similarly, the flow of air which is formed around the radiator 75 by the operation of the arm 3 is generally faster when the radiator 75 is attached to the tip-end part of the upper arm 32 than when the radiator 75 is attached to the base-end part of the upper arm 32. Thus, by disposing the radiator 75 at the part of the arm 3 which moves faster, the cooling of the refrigerant in the radiator 75 can be urged more effectively.

As described in the above embodiment (and Modifications 1 and 2 thereof), the pump 76 may be attached to the arm 3 of the robot 1 in the cooling device 7 described above.

Therefore, as compared with the case where the pump 76 is provided to the base 2 of the robot 1, a distance between the radiator 75 and the pump 76 can be shortened, and therefore, the overall length of the refrigerant circulation channel 70 can be reduced.

As described in the above embodiment, the cooling device 7 described above may be further provided with the air blower 81 which is independent of or separate from the robot 1. When the arm 3 is at the given standby position, before and after the work or operation of the robot 1, or during the work, the air blower 81 is installed so that the radiator 75 is located at the air sending location of the air blower 81.

The air derived from the air blower 81 hits the radiator 75 of the arm 3 located at the standby position to stimulate the heat radiation from the radiator 75. Therefore, even if the radiator 75 is not accompanied with the radiator fan, the refrigerant can be cooled effectively in the radiator 75.

As described in Modifications 1 and 2 of the above embodiment, a part of the refrigerant circulation channel 70 other than the first heat exchanging part 71 and the radiator 75 may be formed as the second heat exchanging part 72 which exchanges heat between the joint actuators D1-D6 of the arm 3 and the refrigerant in the cooling device 7 described above. Note that the heat generating part of the robot 1 includes the joint actuators D1-D6 of the arm 3 in addition to the heat generating part of the end effector 4.

Thus, by the cooling device 7, both the heat generating part of the end effector 4 and the heat generating part of the arm 3 can be cooled.

As described in Modifications 1 and 2 of the above embodiment, the second heat exchanging part 72 may be a channel which passes through the joint actuator of the pivot joint in the cooling device 7 described above. Note that the arm 3 of the robot 1 has at least one pivot joint which serially couples two links so as to be pivotable in a vertical plane. In the arm 3 according to the above embodiment, the second joint JT2 and the third joint JT3 each corresponds to the pivot joint.

In the arm 3 of the robot 1, the load on the joint actuator of the pivot joint is larger and the heat generating amount is larger than the revolute joint or the turning (swivel) joint. Therefore, by the cooling device 7 cooling the joint actuator of the pivot joint of the arm 3, the operation accuracy of the joint actuator can be maintained and the life of the components of the joint actuator can be extended.

As described in Modifications 1 and 2 of the above embodiment, the first heat exchanging part 71 may be located downstream of the second heat exchanging part 72 in the refrigerant circulation channel 70 in the flow direction of the refrigerant.

Therefore, the refrigerant which circulates through the refrigerant circulation channel 70 cools the heat generating part of the end effector 4, after cooling the joint actuators D1-D6. For example, when the end effector 4 is the spot welding gun 40, the spot welding gun 40 has a larger heat generating amount than any one of the joint actuators D1-D6 of the arm 3. Therefore, by the refrigerant flowing as described above, the heat generating part of the end effector 4 can be cooled, without reducing the cooling effect of the joint actuators D1-D6 of the arm 3.

As described in the above embodiment (and Modifications 1 and 2 thereof), the end effector 4 used as the cooling target of the first heat exchanging part 71 may be a resistance-type spot welding gun 40 in the cooling device 7 described above. However, the end effector 4 is not limited to the spot welding gun 40, as long as it has a heat generating part which needs to be forcively cooled. The end effector 4 having such a heat generating part includes a laser welding gun, a chuck for palletizing, and a hand which grips a hot member.

Although a suitable embodiment (and modifications) of the present disclosure is described above, what changed the concrete structure and/or the detail of the function of the above embodiment may be included in the present disclosure, without departing from the sprit of the present disclosure.

### DESCRIPTION OF REFERENCE CHARACTERS

1: Articulated Robot
2: Base
3: Arm
4: End Effector
5: Controller
7: Cooling Device
31: Lower Arm
32: Upper Arm
40: Spot Welding Gun (Example of End Effector)
41: Welding Transformer
42: Weld Gun Body
70: Refrigerant Circulation Channel
71: First Heat Exchanging Part
72: Second Heat Exchanging Part
75: Radiator
76: Pump
81: Air Blower
D: Joint Actuator
E: Rotary Encoder
JT: Joint
L: Link
M: Servomotor
R: Reduction Gear

1. A cooling device configured to cool at least one heat generating part of an articulated robot provided with an arm having a plurality of joints, and an end effector attached to a tip-end part of the arm, comprising:
a refrigerant circulation channel; and
a pump configured to pump refrigerant in the refrigerant circulation channel,
wherein the at least one heat generating part includes a heat generating part of the end effector, and a part of the refrigerant circulation channel is formed as a first heat exchanging part configured to exchange heat between the heat generating part of the end effector and the refrigerant,
wherein another part of the refrigerant circulation channel is formed as a radiator, and
wherein the radiator is a passive radiator, and is attached in an exposed state to a part of the surface of the arm, configured to move in a space when the joint of the arm is driven.

2. The cooling device of claim 1, wherein the arm has a lower arm and an upper arm coupled to a tip-end part of the lower arm, and
wherein the radiator is attached to the upper arm.

3. The cooling device of claim 2, wherein the radiator is attached to a tip-end part of the upper arm.

4. The cooling device of claim 1, wherein the pump is attached to the arm.

5. The cooling device of claim 1, further comprising an air blower independent from the articulated robot,
wherein the air blower is installed so that the radiator is located at an air sending location of the air blower when the arm is located at a given standby position before and after a work, or during the work of the articulated robot.

6. The cooling device of claim 1, wherein the at least one heat generating part includes a joint actuator of the arm, and another part of the refrigerant circulation channel is formed as a second heat exchanging part configured to exchange heat between the joint actuator and the refrigerant.

7. The cooling device of claim 6, wherein the arm has at least one pivot joint serially coupling two links so as to be pivotable in a vertical plane, and the second heat exchanging part is a channel passing through the joint actuator of the pivot joint.

8. The cooling device of claim 6, wherein the first heat exchanging part is located downstream of the second heat exchanging part in a flow direction of the refrigerant in the refrigerant circulation channel.

9. The cooling device of any one of claim 1, wherein the end effector is a spot welding gun.
